(19) United States
(12) Patent Application Publication
(10) Pub. No.: US 2007/0201056 A1
(43) Pub. Date: Aug. 30, 2007

(54) Light-scattering color-conversion material layer

(75) Inventors: Ronald S. Cok, Rochester, NY (US); Mitchell S. Burberry, Webster, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/361,094

(22) Filed: Feb. 24, 2006

(51) Int. Cl. G03F 3/08

(52) U.S. Cl. 358/1.9; 358/518; 358/296

(57) ABSTRACT

A light-scattering color-conversion material layer having two sides, comprising first light-scattering particles intermixed with second different color-conversion material particles, wherein the concentration of the light scattering particles is greater towards a first side of the layer relative to the concentration of light-scattering particles towards the opposite side of the layer, and/or wherein the concentration of the color-conversion material particles is less towards the first side of the layer relative to the concentration of color-conversion material particles towards the opposite side of the layer. A method of making such a light-scattering color-conversion material layer is also described, and light emitting devices comprising one or more EL elements formed on a substrate and such a light-scattering color-conversion material layer optically coupled with the EL element.

### FIELD OF THE INVENTION

The present invention relates to light-scattering color-conversion material layers, and in particular embodiments, to electroluminescent devices including such a layer.

### BACKGROUND OF THE INVENTION

Flat-panel display devices employ a variety of technologies for emitting patterned, colored light to form full-color pixels. Some of these technologies employ a common light-emitter for all of the color pixels and color-conversion materials to convert the light of the common light-emitter into colored light of the desired frequencies. Such unpatterned, common light-emitters may be preferred since patterning colored-light emitters can be difficult. For example, liquid crystal displays (LCDs) typically employ a backlight that relies on either fluorescent tubes to emit a white light or a set of differently colored, inorganic light-emitting diodes to emit white light together with patterned color filters, for example red, green, and blue, to create a full-color display. It is also known to employ the differently colored light-emitting diodes in the set sequentially to create a series of colored backlights in which case color filters may not be necessary. Alternatively, organic light-emitting diodes (OLEDs) may employ a combination of differently colored emitters, or an unpatterned broad-band emitter to emit white light together with patterned color filters, for example red, green, and blue, to create a full-color display. The color filters may be located on the substrate, for a bottom-emitter, or on the cover, for a top-emitter. For example, U.S. Pat. No. 6,392,340 entitled “Color Display Apparatus having Electroluminescence Elements” issued May 21, 2002 illustrates such a device. However, such designs are relatively inefficient since approximately two-thirds of the light emitted may be absorbed by the color filters.

OLEDs rely upon thin-film layers of organic materials coated upon a substrate. OLED devices generally can have two formats known as small-molecule devices such as disclosed in U.S. Pat. No. 4,476,292 and polymer OLED devices such as disclosed in U.S. Pat. No. 5,247,190. Either type of OLED device may include, in sequence, an anode, an organic electroluminescent (EL) element, and a cathode. The organic EL element disposed between the anode and the cathode commonly includes an organic hole-transporting layer (HTL), an emissive layer (EML) and an organic electron-transporting layer (ETL). Holes and electrons recombine and emit light in the EML layer. Tang et al. (Appl. Phys. Lett., 51, 913 (1987), Journal of Applied Physics, 65, 3610 (1989), and U.S. Pat. No. 4,769,292) demonstrated highly efficient OLEDs using such a layer structure. Since then, numerous OLEDs with alternative layer structures, including polymeric materials, have been disclosed and device performance has been improved.

Light is generated in an OLED device when electrons and holes that are injected from the cathode and anode, respectively, flow through the electron transport layer (ETL) and the hole transport layer (HTL) and recombine in the emissive layer (EML). Many factors determine the efficiency of this light-generating process. For example, the selection of anode and cathode materials can determine how efficiently the electrons and holes are injected into the device; the selection of ETL and HTL can determine how efficiently the electrons and holes are transported in the device, and the selection of EML can determine how efficiently the electrons and holes be recombined and result in the emission of light, etc.

In yet another alternative means of providing a full-color OLED device, an OLED device may employ a single high-frequency light emitter together with color-conversion materials (also known as color-change materials or layers) to provide a variety of color light output. The color-conversion materials absorb the high-frequency light and re-emit light at lower frequencies. For example, an OLED device may emit blue light suitable for a blue sub-pixel and employ a green color-conversion material to absorb blue light and emit green light and employ a red color-conversion materials to absorb blue light and emit red light. The color-conversion materials may be combined with color filters to further improve the color of the emitted light and to absorb incident light and avoid exciting the color-conversion materials with ambient light, thereby improving device contrast. US20050116621 A1 entitled “Electroluminescent devices and methods of making electroluminescent devices including a color-conversion element”, e.g., describes the use of color-conversion materials.

U.S. Patent Application 20040233139A1 discloses a color-conversion member which is improved in the prevention of a deterioration in color-conversion function, the prevention of reflection of external light, and color rendering properties. The color-conversion member comprises a transparent substrate, two or more types of color-conversion layers, and a color-filter layer. The color-conversion layers function to convert incident lights for respective sub-pixels to outgoing lights of colors different from the incident lights. The two or more types of color-conversion layers are arranged on said transparent substrate. The color-filter layer is provided on the transparent substrate side of any one of the color-conversion layers or between the above any one of the color conversion layers and the color conversion layers adjacent to the above any one of the color-conversion layers. U.S. patent application 20050057177 also describes the use of color-conversion materials in combination with color filters.

It has also been found that one of the key factors that limits the efficiency of OLED devices is the inefficiency in extracting the photons generated by the electron-hole recombination out of the OLED devices. Due to the high optical indices of the organic materials used, most of the photons generated by the recombination process are actually trapped in the devices due to total internal reflection. These trapped photons never leave the OLED devices and make no contribution to the light output from these devices. Because light is emitted in all directions from the internal layers of the OLED, some of the light is emitted directly from the device, and some is emitted into the device and is either reflected back out or is absorbed, and some of the light is emitted laterally and trapped and absorbed by the various layers comprising the device. In general, up to 80% of the light may be lost in this manner.

A typical OLED device uses a glass substrate, a transparent conducting anode such as indium-tin-oxide (ITO), a stack of organic layers, and a reflective cathode layer. Light generated from the device is emitted through the glass substrate. This is commonly referred to as a bottom-emitting device. Alternatively, a device can include a substrate, a reflective anode, a stack of organic layers, and a top transparent cathode layer. Light generated from the device is emitted through the top transparent electrode. This is commonly referred to as a top-emitting device. In these typical devices, the index of the ITO layer, the organic layers, and the glass is about 1.8-2.0, 1.7, and 1.5 respectively. It has been estimated that nearly 60% of the generated light is trapped by internal reflection in the ITO/organic EL element, 20% is trapped in the glass substrate, and only about 20% of the generated light is actually emitted from the device and performs useful functions.

A variety of techniques have been proposed to improve the out-coupling of light from thin-film light emitting devices. For example, diffraction gratings have been proposed to control the attributes of light emission from thin polymer films by inducing Bragg scattering of light that is guided laterally through the emissive layers; see “Modification of polymer light emission by lateral microstructure” by Safonov et al., Synthetic Metals 116, 2001, pp. 145-148, and “Bragg scattering from periodically microstructured light emitting diodes” by Lupton et al., Applied Physics Letters, Vol. 77, No. 21, Nov. 20, 2000, pp. 3340-3342. Brightness enhancement films having diffractive properties and surface and volume diffusers are described in WO0237568 A1 entitled “Brightness and Contrast Enhancement of Direct View Emissive Displays” by Chou et al., published May 10, 2002. The use of micro-cavity techniques is also known; for example, see “Sharply directed emission in organic electroluminescent diodes with an optical-microcavity structure” by Tsutsui et al., Applied Physics Letters 65, No. 15, Oct. 10, 1994, pp. 1868-1870. However, none of these approaches cause all, or nearly all, of the light produced to be emitted from the device. Moreover, such diffractive techniques cause a significant frequency dependence on the angle of emission so that the color of the light emitted from the device changes with the viewer's perspective. Co-pending, commonly assigned U.S. Ser. No. 11/095,166, filed Mar. 31, 2005, describes the use of a micro-cavity OLED device together with a color filter having scattering properties and intended to reduce the angular dependence and color purity of the OLED.

Scattering techniques are also known. Chou (International Publication Number WO 02/37580 A1) and Liu et al. (U.S. Patent Application Publication No. 2001/0026124 A1) taught the use of a volume or surface scattering layer to improve light extraction. The scattering layer is applied next to the organic layers or on the outside surface of the glass substrate and has optical index that matches these layers. Light emitted from the OLED device at higher than critical angle that would have otherwise been trapped can penetrate into the scattering layer and be scattered out of the device. The efficiency of the OLED device is thereby improved but still has deficiencies as explained below.

U.S. Pat. No. 6,787,796 entitled “Organic electroluminescent display device and method of manufacturing the same” by Do et al issued 20040907 describes an organic electroluminescent (EL) display device and a method of manufacturing the same. The organic EL device includes a substrate layer, a first electrode layer formed on the substrate layer, an organic layer formed on the first electrode layer, and a second electrode layer formed on the organic layer, wherein a light loss preventing layer having different refractive index areas is formed between layers of the organic EL device having a large difference in refractive index among the respective layers. U.S. Patent Application Publication No. 2004/0217702 entitled “Light extracting designs for organic light emitting diodes” by Garner et al., similarly discloses use of microstructures to provide internal refractive index variations or internal or surface physical variations that function to perturb the propagation of internal waveguide modes within an OLED. When employed in a top-emitter embodiment, the use of an index-matched polymer adjacent the encapsulating cover is disclosed.

Light-scattering layers used externally to an OLED device are described in U.S. Patent Application Publication No. 2005/0018431 entitled “Organic electroluminescent devices having improved light extraction” by Shiang and U.S. Pat. No. 5,955,837 entitled “System with an active layer of a medium having light-scattering properties for flat-panel display devices” by Horikx, et al. These disclosures describe and define properties of scattering layers located on a substrate in detail. Likewise, U.S. Pat. No. 6,777,871 entitled “Organic ElectroLuminescent Devices with Enhanced Light Extraction” by Duggal et al., describes the use of an output coupler comprising a composite layer having specific refractive indices and scattering properties. While useful for extracting light, this approach will only extract light that propagates in the substrate and will not extract light that propagates through the organic layers and electrodes.

It is also known to employ scattering materials within color filters to combine the functions into a single layer. For example, U.S. Pat. No. 6,731,359 describes color filters that include light scattering fine particles and has a haze of 10 to 90. The inclusion of the light-scattering fine particles within the color filter can impart a light scattering function to the color filter per se. This can eliminate the need to provide a front scattering plate on the color filter (in its viewer side). Further, a deterioration in color properties caused by light scattering can be surely compensated for by the color property correction of the colored layer per se and/or by the correction of color properties through the addition of a colorant. This is suitable for surely preventing deterioration in color properties of the color filter per se.

However, scattering techniques, by themselves, cause light to pass through the light-absorbing material layers multiple times where they are absorbed and converted to heat. Moreover, trapped light may propagate a considerable distance horizontally through the cover, substrate, or organic layers before being scattered out of the device, thereby reducing the sharpness of the device in pixellated applications such as displays. A light ray emitted from the light-emitting layer may be scattered multiple times, while traveling through the substrate, organic layer(s), and transparent electrode before it is emitted from the device. When the light ray is finally emitted from the device, the light ray may have traveled a considerable distance through the various device layers from the original sub-pixel location where it originated to a remote sub-pixel where it is emitted, thus reducing sharpness. Most of the lateral travel occurs in the substrate, because that is by far the thickest layer in the package. Also, the amount of light emitted is reduced due to absorption of light in the various layers.

U.S. Patent Application Publication No. 2004/0061136 entitled “Organic light emitting device having enhanced light extraction efficiency” by Tyan et al., describes an enhanced light extraction OLED device that includes a light scattering layer. In certain embodiments, a low index isolation layer (having an optical index substantially lower than that of the organic electroluminescent element) is employed adjacent to a reflective layer in combination with the light scattering layer to prevent low angle light from striking the reflective layer, and thereby minimize absorption losses due to multiple reflections from the reflective layer. The particular arrangements, however, may still result in reduced sharpness of the device.

Co-pending, commonly assigned U.S. Ser. No. 11/065,082, filed Feb. 24, 2005, describes the use of a transparent low-index layer having a refractive index lower than the refractive index of the encapsulating cover or substrate through which light is emitted and lower than the organic layers to enhance the sharpness of an OLED device having a scattering element. US patent application 20050194896 describes a nano-structure layer for extracting radiated light from a light-emitting device together with a gap having a refractive index lower than an average refractive index of the emissive layer and nano-structure layer. In various described embodiments, such nano-structure layer may be used in combination with color conversion or color filter layers. Such disclosed designs still, however, do not completely optimize the use of emitted light, particularly for displays with a white emitter.

It is also known to combine layers having color-conversion materials with scattering particles to enhance the performance of the color-conversion materials by increasing the likelihood that incident light will interact with the color-conversion materials, thereby reducing the concentration or thickness of the layer. Such combination may also prevent light emitted by the color-conversion material from being trapped in the color-conversion material layer. US20050275615 A1 entitled “Display device using vertical cavity laser arrays” describes such a layer as does US20040252933 entitled “Light Distribution Apparatus”. US20050012076 entitled “Fluorescent member, and illumination device and display device including the same” teaches the use of color-conversion materials as scattering particles. US20040212296 teaches the use of scattering particles in a color-conversion material layer to avoid trapping the frequency-converted light. However, none of these designs effectively combine light extraction from an OLED device with efficient color-conversion.

For any practical OLED device, it is important to minimize the cost and maximize the manufacturing yield and performance of the device. There is a need therefore for improved organic light-emitting diode devices, and processes for forming such devices that reduces costs, and improves yields, and improves performance.

### SUMMARY OF THE INVENTION

In accordance with one embodiment, the invention is directed towards a light-scattering color-conversion material layer having two sides, comprising first light-scattering particles intermixed with second different color-conversion material particles, wherein the concentration of the light scattering particles is greater towards a first side of the layer relative to the concentration of light-scattering particles towards the opposite side of the layer, and/or wherein the concentration of the color-conversion material particles is less towards the first side of the layer relative to the concentration of color-conversion material particles towards the opposite side of the layer. In accordance with further embodiments, the invention is also directed towards a method of making such a light-scattering color-conversion material layer, and to a light emitting device comprising one or more EL elements formed on a substrate and such a light-scattering color-conversion material layer optically coupled with the EL element.

### ADVANTAGES

The present invention has the advantage that it enables improved performance and reduces the cost of electroluminescent devices, and in particular of OLED devices.

### BRIEF DESCRIPTION OF THE DRAWINGS

FIGS. 1A-1C illustrate cross sections of various embodiments of integral light-scattering color-conversion material layers having a thick matrix, a thin matrix, and no matrix, respectively according to alternative embodiments of the present invention;

FIG. 2 illustrates a cross section of an active-matrix top-emitter OLED device having an optically active light-scattering color-conversion material layer according to an embodiment of the present invention;

FIG. 3 is a flow diagram according to a method of forming an electroluminescent device including an integral light-scattering color-conversion material layer in accordance with the present invention.

It will be understood that the figures are not to scale since the individual layers are too thin and the thickness differences of various layers too great to permit depiction to scale.

### DETAILED DESCRIPTION OF THE INVENTION

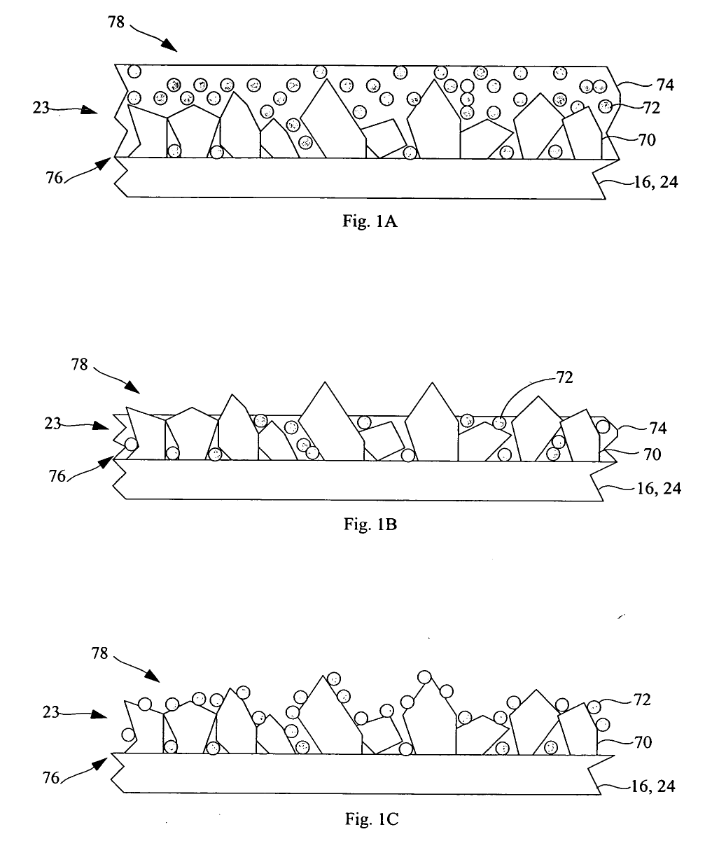

Referring to FIG. 1A, in one embodiment of the present invention, a light-scattering color-conversion material layer 23 having two sides 76, 78, comprising first light-scattering particles 70 intermixed with second different color-conversion material particles 72. The first light-scattering particles 70 are integrally intermixed with the different color-conversion material particles 72 to form a common light-scattering color-conversion material layer 23 with at least one constituent having varying concentrations at different locations through the thickness of the light-scattering color-conversion material layer 23. In particular, in the embodiment of FIG. 1A, the concentration of the light scattering particles 70 is greater towards a first side 76 of the layer 23 relative to the concentration of light-scattering particles 70 towards the opposite side 78 of the layer, and the concentration of the color-conversion material particles 72 is less towards the first side 76 of the layer relative to the concentration of color-conversion material particles 72 towards the opposite side 78 of the layer. While the concentration of either of the light-scattering particles or the color-conversion materials may be varied through the integral layer in accordance with the invention, in a preferred embodiment both such concentrations are varied. By varying the concentration of light-scattering particles in the integral layer, light-extraction from an associated light-emitting device may be optimized while minimizing unnecessary reflection back towards the associated light-emitting device. By varying the concentration of color-conversion materials in the integral layer, light extraction at the interface is not inhibited, while the efficiency of color-conversion may be optimized. By varying both concentrations in the integral layer in accordance with preferred embodiments, light extraction and color conversion may be simultaneously and synergistically optimized. In particular, Applicants have empirically found that larger particles of a higher index may be more effective at light extraction when located at higher concentrations at an interface with an EL device when color conversion materials with smaller particles having a lower index are located between and above the light-scattering particles.

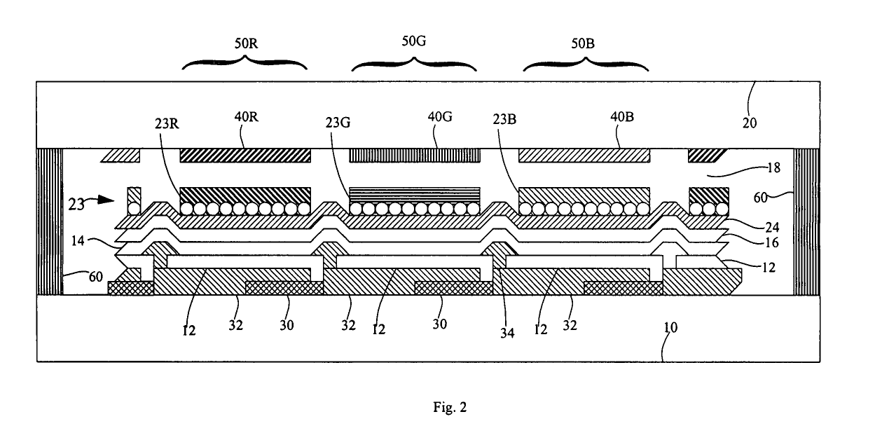

Referring to FIG. 2, according to an active-matrix embodiment of the present invention, a light-emitting device comprises one or more EL elements formed on a substrate 10; and a light-scattering color-conversion material layer 23 optically coupled with the EL element. The EL element may be formed from a reflective, patterned electrode 12 formed on a substrate 10 with thin-film electronic component 30 and passivation and insulating layers 32 and 34, one or more organic layers 14, at least one of which is light emitting, and an unpatterned transparent electrode 16. An optional electrode protection layer 24 may be provided over the transparent electrode 16. The light emitted from the EL element at a first frequency is absorbed and re-emitted by the color-conversion material of layer 23 at a second, lower frequency and light emitted from, and entrapped in, the EL element is extracted by the light-scattering particles of layer 23. As illustrated in FIG. 1A, e.g., the concentration of the light scattering particles 70 is greater towards a first side of the layer 23 adjacent to the EL element layer 16 relative to the concentration of light-scattering particles towards the opposite side of the layer, and the concentration of the color-conversion material particles 72 is less towards the first side of the layer 23 relative to the concentration of color-conversion material particle towards the opposite side of the layer. In a preferred embodiment, the EL element is an OLED element.

Light-scattering color-conversion material layer 23 may be patterned over the one or more light-emitting areas defined by the patterned electrode 12 for scattering and color-converting light emitted by the one or more layers 14 of light-emitting organic material. Different portions 23R, 23G, 23B of the light-scattering color-conversion material layer 23 may emit light of different colors by patterning different color-conversion material particles 72 in the different portions. One or more optional color filters 40R, 40G, 40B may be formed on a transparent cover 20. The substrate 10 is aligned and affixed to the transparent cover 20 so that the locations of the color filters and different color conversion materials in the optically active layer 23 correspond to the location of the OLEDs. A low-index gap 18 may be formed between the optically active layer 23 and the cover 20.

In one embodiment of the present invention, an OLED device incorporating a patterned light-scattering color-conversion material layer 23 includes color filters comprising red 40R, green 40G, and blue 40B color filters patterned in a common layer. Likewise, the color conversion material particles 72 in light-scattering color-conversion material layer 23 may comprise red, green, and blue color-conversion materials.

Preferably, at least one half, and more preferably substantially all, of the surface of the EL element is covered with light-scattering particles 70. The light-scattering particles 70 of the light scattering color-conversion material layer 23 are typically adjacent to and in optical contact with, or within 500 nm (preferably less than 200 nm and more preferably less than 100 nm) of an EL element to defeat total internal reflection in the organic layers 14 and transparent electrode 16. By optical contact is meant that light that is trapped in the OLED interacts with the light-scattering particles 70 to be scattered out of the OLED. According to an embodiment of the present invention, light emitted from the organic layers 14 can waveguide along the organic layers 14 and transparent electrode 16 combined, since the organic layers 14 have a refractive index lower than that of the transparent electrode 16 and electrode 12 is reflective. The light-scattering color-conversion material layer 23 disrupts the total internal reflection of light in the combined layers 14 and 16 and redirects some portion of the light out of the combined layers 14 and 16. The re-directed light and directly emitted light, then encounters the color-conversion materials 72 and, for light having a frequency higher than the re-emission frequency of the color-conversion materials, absorbs the light and re-emits it. Any scattered emitted or re-emitted light that subsequently waveguides within the light-scattering color-conversion material layer 23 will be re-scattered until it is emitted into the low-index layer 18. Scattered light that is emitted or re-emitted may also escape directly into the low-index layer 18. Any light that travels into the low-index layer 18 will then pass through the color filters 40 and thence out of the OLED device. To facilitate this effect, the transparent low-index layer 18 should not itself scatter light, and should be as transparent as possible. The transparent low-index layer 18 is preferably at least one micron thick and has an optical index lower than that of the color filters 40 or cover 20 to ensure that emitted light properly propagates through the transparent low-index element and is transmitted through the cover 20. In one embodiment, the low-index layer 18 is a gap containing a gas or vacuum.

As shown in FIG. 1A, the color-conversion materials 72 are distributed throughout a transparent matrix 74 and between and intermixed with the light-scattering particles 70. The light-scattering particles 70 are typically much larger than the color-conversion material particles or molecules 72. According to a further embodiment of the present invention, the light-scattering particles 70 of the light-scattering color-conversion material layer 23 have a first average size and the color-conversion particles 72 have a second average size smaller than the first average size. Applicants have determined that, surprisingly and contrary to theoretical calculations using Mies theory, the optimal average maximum dimension size of light-scattering particles 72 may be greater than or equal to 400 nm in diameter and preferably have an average maximum dimension size less than two microns and more preferably have an average maximum dimension size between one and two microns while the color-conversion materials are preferably less than 400 nm in diameter, and may be less than 100 nm or even less than 10 nm in diameter. This may be due to the fact that important assumptions of Mies theory are not met with a randomly oriented layer of arbitrarily shaped particles that are not strictly in a mono-layer.

Light-scattering particles 70 of the present invention may serve at least three functions. A first function is to extract trapped light from the OLED device. To enable this, the light-scattering particles 70 must be in contact or very close to (less than the wavelength of light distant) to a transparent layer of the OLED (the electrode 16 or electrode protection layer 24, in this example). At the same time, a second function of the light-scattering particles 70 is to enhance the likelihood that extracted OLED light will encounter the color-conversion material 72 in as short a path length as possible to reduce light absorption. Because the color-conversion materials 72 tend to quench each other, they must be located somewhat distant from each other; by intermixing the color-conversion materials 72 in an integral layer with the light-scattering particles 70, the extracted OLED light will be reflected or refracted in many directions before it escapes from the light-scattering color-conversion material layer 23, increasing the likelihood that the extracted light will be frequency-converted and thereby reducing the required thickness of the integral light-scattering color-conversion material layer 23 and the amount of color-conversion material 72. A third function of the light-scattering particles 70 is to scatter the frequency-converted light. Because the particles may emit light within a matrix 74 having an optical index higher than that of air and may be adjacent to a low-index layer (e.g. 18), frequency-converted light may be trapped within the matrix 74 in a fashion similar to the trapped OLED light. The light-scattering particles 70 (and to a lesser extent, the color-conversion materials 72) may scatter this trapped frequency-converted light so it can be emitted from the OLED device. Because the extracted OLED light is of a different frequency from the scattered, frequency-converted light, it is most helpful if the scattering particles 70 form a multi-frequency scattering layer 23 so that the particles 70 effectively scatter light of at least two colors and, more preferably form a broadband light scattering layer. Moreover, it is important not to absorb any light of the desired frequency that is extracted from the OLED device. Hence, it is important to balance the thickness of the light-scattering color-conversion material layer 23 and the concentration of the color-conversion materials 72 to optimize the output of light of the desired frequency.

Such an integral light-scattering color-conversion material layer 23 may be formed by first depositing a layer of light-scattering particles 70 in a solvent and an optional binder and/or surfactant. For example, applicants have effectively coated such a layer by employing titanium dioxide in toluene or xylene with an optional urethane binder and surfactant. The optional binder is included in very small amounts to act as a surfactant and adhesive and does not necessarily, but may in larger amounts, serve as a matrix 74. The solution may be coated by employing any of a variety of coating methods, including spin, jet, hopper, and spray coating, as demonstrated by Applicant. The coated solvent evaporates, leaving a layer of scattering particles 70 adhered to a surface, for example an electrode protection layer 24. In a second step, a matrix 74, for example a polymer or resin, containing a dispersion of color-conversion particles 72 with or without a surfactant to prevent flocculation and to aid capillary action, is coated over the layer of light-scattering particles 70 using any of the above-listed methods. Capillary action causes the matrix 74 dispersion to intermix by flowing over, into, and between the light-scattering layer and particles 70 to form an integral light-scattering and color-conversion material layer 23. Applicants have effectively demonstrated this process and the action of the light-scattering particles 70 and the color-conversion material 72. Alternatively, the light-scattering color-conversion material layer 23 of the present invention may comprise a matrix 74 in which either or both of the light-scattering particles 70 and/or color-change material particles 72 are dispersed. In a further embodiment of the present invention, the matrix may be a polymer, resin, or urethane, or a curable material. By employing a curable material, the particles 70, 72 in the light-scattering color-conversion layer 23 may be more readily adhered and may be more robust in the presence of environmental stress.

In one embodiment of the present invention, the light-scattering color-conversion layer 23 may be formed on a surface or substrate of an EL device. Alternatively, the light-scattering color-conversion layer 23 may be formed as a self-supporting layer (e.g., by casting or extrusion) that can be subsequently applied to a light-emitting device. Alternatively, layer 23 may be formed on a temporary support, applied to an EL device, and the temporary support then may be removed.

According to the present invention, such an integral light-scattering and color-conversion material layer 23 may be advantageously employed to extract light from the organic light-emitting layer(s) 14 and to convert the extracted light into light having a preferred spectrum. Such a combined, integral layer may have advantages in deposition or performance, for example the scattering materials, e.g. particles 70, may be mixed with the color-conversion materials 72 in a common solvent and/or matrix 74 and deposited in a single step. Since the color-conversion materials 72 may include dyes comprising relatively small molecules within the matrix 74, the color-conversion materials may not interfere with the light extraction. Alternatively, if small, light-converting particles 72 are employed, the particles 72 are typically smaller (e.g. less than 10 nm in diameter) than the multi-frequency light-scattering particles 70 preferred for the current invention and do not interfere with light extraction. If some scattering due to the light-converting particles 72 does take place, the additional scattering is not likely to inhibit the light extraction and may, in fact, aid it. Moreover, the integration of the color-changing materials 72 in the light-scattering color-conversion material layer 23 may enhance the light conversion by increasing the likelihood that an incident photon will encounter a color conversion material particle 72. Furthermore, the light-scattering particles 70 in the integral light-scattering color-conversion material layer 23 will serve to scatter converted light that may waveguide in the color-conversion material 72 or matrix 74. Both light-converting dyes and particles are known in the art.

In the embodiment of the present invention illustrated in FIG. 1A, the light-scattering color-conversion material layer 23 is thicker than the size of the light-scattering particles 70 so that the light-scattering particles 70 are covered by a matrix 74. Hence, the concentration of light-scattering particles 70 is highest on the side 76 and lower on side 78. In contrast, the concentration of color-conversion particles 72 is highest on the opposite side 78 and lower on side 76. Preferably, the matrix 74 has a low optical index; however, it is difficult to form a matrix 74 having an optical index as low as that of the low-index medium 18. While this is effective and enables a relatively thick light-scattering color-conversion layer 23 with a relatively large amount of color-conversion material thereby improving the amount of color-converted light, the difference in optical refractive index between the light-scattering particles 70 and the matrix 74 will typically be less than the difference in optical index between the light-scattering particles 70 and the low-index layer 18. This difference of the optical refractive index of the two media can reduce the light extraction effectiveness of the light-scattering layer for the trapped OLED light. Hence, in an alternative embodiment illustrated in FIG. 1B, the matrix 74 is coated in a thinner layer that is approximately as thick as, or thinner than, the size of the light-scattering particles 70. In this embodiment, a fraction of the light-scattering particles 70 extend into the low-index medium 18, maintaining the optical refractive difference between and enhancing the light-extraction effectiveness of the light-scattering color-conversion layer 23.

In the embodiment of FIG. 1B, the concentration of color-conversion particles 72 in matrix 74 is higher on the side 76, as none are located at the opposite side 78 where the light-scattering particles 70 extend past the matrix 74. In this embodiment, a surface connecting only the peaks of the light-scattering particles 70 extending above the matrix 74 of layer 23 is considered the surface 78 of layer 23. In the embodiments of FIGS. 1A and 1B, the matrix 74 serves as a useful medium for carrying the color-conversion materials 72 and an aid to the intermixing of the color-conversion materials 72 with the light-scattering particles 70 by capillary action. The light-scattering color-conversion layer 23 of FIG. 1A may be usefully formed in two steps while the light-scattering color-conversion layer 23 of FIG. 1B may be usefully formed in either one or two steps.

In an alternative embodiment illustrated in FIG. 1C, no matrix 74 is employed and color-conversion materials 72 are dispersed in, for example, a solvent or gas using coating methods described above, that distributes the color-conversion materials 72 over and between the light-scattering particles 70 to form integral layer 23. In this embodiment, the concentration of color-conversion particles 72 is highest on the opposite side 78, since, for the most part, color-conversion particles 72 deposited over light-scattering particles 70 will remain on the upper surfaces of the light-scattering particles and primarily on the opposite side 78. To aid adhesion, an adhesive, for example urethane, may be employed with the light-scattering particles 70 or color-conversion material 72. In this embodiment, the optical index difference and light extraction effectiveness is even greater than in the previous embodiment. Moreover, frequency-converted light cannot be trapped in the matrix 74 since, in this embodiment, no such layer is provided. A similar effect obtained by providing such a rough surfaced scattering layer is described in further detail in concurrently-filed, commonly-assigned, co-pending U.S. Ser. No. ______ (Kodak Docket No. 92209), the disclosure of which is incorporated herein by reference.

According to the present invention, a color-conversion material corresponding to a color filter 40 (e.g., 40R, 40G, 40B) means that the color-conversion material converts incident light from the light-emissive layer 14 to a lower-frequency light whose frequency range overlaps the frequency range of the light passed by the color filter 40. For example, a light-scattering color-conversion layer 23R that converts incident light to a substantially red color corresponds in location to a substantially red color filter 40R. Likewise, a light-scattering color-conversion layer 23G may convert incident light to a substantially green color corresponding in location to a substantially green color filter 40G and a light-scattering color-conversion layer 23B that converts incident light to a substantially blue color corresponds in location to a substantially blue color filter 40B. If the light-emitting organic layer 14 emits blue light or a broadband white light including blue light, the light-scattering color-conversion layer 23B may be omitted.

As used herein, a color filter is a layer of light-absorptive material that strongly absorbs light of one frequency range but largely transmits light of a different frequency range. For example, a red color filter will mostly absorb green- and blue-colored light while mostly transmitting red-colored light. Such color filter materials typically comprise pigments and dyes but, as used herein, explicitly exclude fluorescent and phosphorescent materials. In various embodiments of the present invention, a color filter may be employed as trimming filters to further control the emitted color and to absorb ambient light. This absorption of ambient light will also have the beneficial effect of reducing any stimulation of the color-conversion material by ambient light, thereby improving contrast. As used herein, a color-conversion material (CCM), also known as a color-change material, or color-conversion layer, is a layer of material that absorbs light of one frequency range and re-emits light at a second, lower frequency range. Such materials are typically fluorescent or phosphorescent. Both materials are known in the prior art, however the color-conversion materials are occasionally referred to as color filters. In the present invention color filters never emit light, they only absorb light.

The light-scattering color-conversion layer 23 is formed over the transparent electrode 16. A protective layer 24 may be formed over the transparent electrode 16 to protect it from environmental contaminants due to manufacturing processes (such as the deposition of the optically active layer 23) or to use. The cover 20 and substrate 10 are affixed in alignment using, for example, an encapsulating adhesive 60, so that the light-emitting areas 50R, 50G, 50B of the OLED are aligned with the light-scattering color-conversion layer 23 and color filters 40 to optimize the emission of light from the light-emissive organic material layer 14 into the color-conversion layer and thence through the color filter 40 and the cover 20. A low-index layer 18 is provided between the layer 23 and the color filters 40. The use of a scattering layer in combination with a low-index element 18 is described in co-pending, commonly assigned U.S. Ser. No. 11/065,082, filed Feb. 24, 2005, the disclosure of which is incorporated by reference herein, and is also discussed in further detail below.

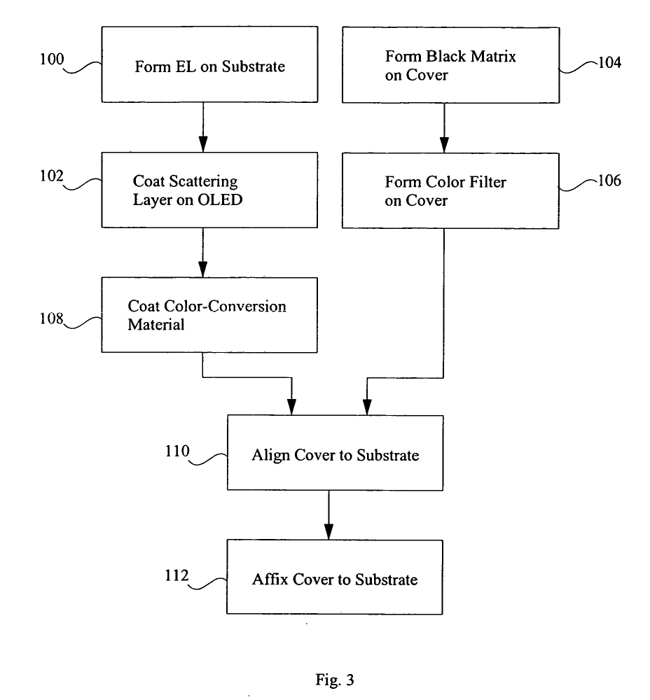

Referring to FIG. 3, an electroluminescent device incorporating a light-scattering color-conversion material layer may be formed by first forming 100 an EL element on a substrate, and subsequently forming the light-scattering color-conversion material layer on the EL element. A method of forming a light-scattering color-conversion material layer on the EL element comprises the steps of coating 102 a first layer comprising light-scattering particles on the EL device and then coating 108 a second layer comprising color-conversion material particles over the first layer, wherein the color-conversion material particles and light-scattering particles intermix at the interface of the first and second layers to form an integral layer, wherein the concentration of the light scattering particles is greater towards a first side of the integral layer relative to the concentration of light-scattering particle towards the opposite side of the integral layer, or wherein the concentration of the color-conversion material particles is less towards the first side of the integral layer relative to the concentration of color-conversion material particle towards the opposite side of the integral layer.

In a further embodiment of the method of forming a light-scattering color-conversion material layer of the present invention, light-scattering particles and/or color-change material particles may be mixed in a matrix material and the mixture coated on a substrate. In an alternative embodiment of the present invention, the light-scattering particles may be mixed in a solvent and the color-change material particles mixed in a matrix material, the solvent mixture coated as the first layer, and the matrix mixture coated as the second layer. Alternatively, the light-scattering particles may be mixed in a first solvent and the color-change material particles mixed in a second solvent, the first solvent mixture coated as the first layer, and the second solvent mixture coated as the second layer. These alternative embodiments provide methods of making the light-scattering color-conversion layer of the present invention as illustrated in FIGS. 1A-1C.

As further illustrated in FIG. 3, in a separate operation, a black matrix may be formed 104 on a cover, color filters likewise formed 106 on the cover, and the cover aligned 110 to the substrate and affixed 112 thereto to form a completed EL device. Fabrication of EL devices incorporating light-scattering and color-conversion materials and color filter materials by alignment and adherence of separate elements coated on separate substrates is also described in concurrently-filed, commonly-assigned, co-pending U.S. Ser. No. ______ (Kodak Docket No. 92015), the disclosure of which is incorporated herein by reference.

The present invention is also preferred to the prior art by employing two separate manufacturing processes, one for the substrate 10 and the layers formed thereon and the second for the cover 20 and the layers formed thereon. Conventional OLED manufacturing processes have relatively low yields for the TFT components 30 and organic layers 14. If the color filters 40 and black matrix 41 were subsequently formed over the OLED layers, the yields would be reduced. If, according to the present invention, the color filters 40 and black matrix are formed on a separate cover 20, they can be separately qualified and combined with similarly qualified substrates 10, thereby improving the overall yield.

Moreover, it is difficult to pattern elements such as black-matrix materials and color filters 40 over the organic layers 14. Photolithographic processes, including chemicals and ultra-violet light, can be quite damaging to the organic materials and extra, protective layers 24 may be necessary to prevent such damage. Even deposition processes such as inkjet typically include solvents that may damage the OLED material. The low-index element 18 is also difficult to form and depositing layers such as color filters 40 over the low-index element 18 without destroying the OLED layers may be exceedingly difficult. Hence, the formation of the black-matrix and color filters 40 on the cover 20 followed by alignment and affixing to the substrate 10 will improve yields and reduce manufacturing costs.

In operation, when stimulated by a current controlled by the thin-film electronic components 30, the light-emitting layer 14 may emit a broadband white light, an ultra-violet light, a blue light, or a broadband light including blue light or ultra-violet light. Due to internal reflections, at least some portion of this light is trapped in the organic layers 14 and transparent electrode 16. The light-scattering particles 70 of the light-scattering color-conversion layer 23 scatters the trapped light and other light into the color-conversion material 72. The color conversion materials 72 in the light-scattering color-conversion layer layer 23R convert the incident light into red light for red light-emitting element 50R, color conversion materials 72 in the light-scattering color-conversion layer layer 23G converts the incident light into green light for green light-emitting element 50G, and the color conversion materials 72 in light-scattering color-conversion layer 23B, if present, converts the incident blue or ultra-violet light into blue light for blue light-emitting element 50B. The color-conversion materials 72 emit light in every direction.

In the configuration of FIG. 2, some of the light may be emitted toward or trapped in the light-scattering color conversion layer 23. The light-scattering particles 70 will then scatter the converted light into an angle that allows the light to escape into the low-index layer 18 and thence from the EL device. Light-scattering particles 70 preferably provide a multi-frequency (or pan-chromatic) scattering layer capable of scattering light of a variety of frequencies, including broadband light (or white light) and a variety of colored lights, for example blue, green, and red. Hence, the light-scattering color-conversion layer 23 preferably can scatter both the emitted light and the converted light, of whatever frequencies, so that only a single scattering layer is necessary in the device. A single scattering layer reduces the number of reflections and the average path length of the light, thereby reducing absorption and improving the light output. Moreover, the use of a single, multi-frequency light-scattering color-conversion layer 23 to scatter light of at least two different frequency ranges, or colors, reduces costs and improves yields. Applicants have constructed a suitable light-scattering color-conversion layer optically integrated with an OLED device.

The light-emitting elements of the present invention may be independently controlled and grouped into full-color pixels and a plurality of such pixels provided to form a display device. Each color of the color filters may be formed in a common manufacturing step, as may each color of the color-conversion materials. According to a further embodiment of the present invention, the display device may have two independently controllable light-emitting elements that employ color filters and color conversion material and emit red and green light respectively and a third independently controllable light-emitting element that emits blue light and optionally includes a color filter and color conversion layer.

In various embodiments of the present invention, an OLED device may comprise a plurality of independently-controllable light-emitting elements forming a full-color display device. For example, the independently controllable light-emitting elements may be grouped into full-color pixels, each having at least a red, green, and blue light emitter. The one or more layers 14 of light-emitting organic material may emit broadband light that contains at least two colors of light, the color-conversion material 72 may comprise material that converts relatively higher frequency components of the broadband light to lower frequency light, and the color filters 40 may be correspondingly patterned with the color-conversion material to form sub-pixel elements emitting different colors of light. In a particular embodiment, the one or more layers 14 of light-emitting organic material emit broadband light that contains blue and at least one other color of light, a color-conversion material that converts relatively higher frequency components of the broadband light to green light is correspondingly patterned with at least one of the OLEDs to form a green sub-pixel, a color-conversion material that converts relatively higher frequency components of the broadband light to red light is correspondingly patterned with at least one other of the OLEDs to form a red sub-pixel, and a blue color filter directly filtering emitted broadband light is correspondingly patterned with at least one additional other of the OLEDs to form a blue sub-pixel. Furthermore, the green color filters may be correspondingly patterned with the green sub-pixels and/or red color filters correspondingly patterned with the red sub-pixels. In a specific embodiment of the present invention, the broadband light may be substantially white. Moreover, each pixel may further comprise a white sub-pixel that may not need any filters. This white sub-pixel may be used in combination with red, green, and blue sub-pixels to form an RGBW pixel having higher efficiency than a conventional OLED device having a white OLED emitter in combination with red, green, and blue color filters alone.

In preferred embodiments, the cover 20 and substrate 10 may comprise glass or plastic with typical refractive indices of between 1.4 and 1.6. The transparent low-index layer 18 may comprise a void, or may be filled with a solid, liquid, or gaseous layer of optically transparent material. Voids or gaps may be a vacuum or filled with an optically transparent gas or liquid material. For example air, nitrogen, helium, or argon all have a refractive index of between 1.0 and 1.1 and may be employed. Lower index solids which may be employed include fluorocarbon or MgF, each having indices less than 1.4. Any gas employed is preferably inert. Reflective electrode 12 is preferably made of metal (for example aluminum, silver, or magnesium) or metal alloys. Transparent electrode 16 is preferably made of transparent conductive materials, for example indium tin oxide (ITO) or other metal oxides. The organic material layer(s) 14 may comprise organic materials known in the art, for example, hole-injection, hole-transport, light-emitting, electron-injection, and/or electron-transport layers. Such organic material layers are well known in the OLED art. The organic material layer(s) 14 typically have a refractive index of between 1.6 and 1.9, while indium tin oxide has a refractive index of approximately 1.8-2.1. Hence, the various organic and transparent electrode layers in the OLED have a refractive index range of 1.6 to 2.1. Of course, the refractive indices of various materials may be dependent on the wavelength of light passing through them, so the refractive index values cited here for these materials are only approximate. In any case, the transparent low-index layer 18 preferably has a refractive index at least 0.1 lower than that of each of the first refractive index range and the second refractive index at the desired wavelength for the OLED emitter.

In certain embodiments layer 23 may comprise materials having at least two different refractive indices. The light-scattering color-conversion layer 23 may comprise, e.g., a matrix of lower refractive index and scattering elements having a higher refractive index. Alternatively, the matrix 74 may have a higher refractive index and the scattering elements may have a lower refractive index. For example, the matrix may comprise silicon dioxide or cross-linked resin having indices of approximately 1.5, or silicon nitride with a much higher index of refraction. It is desirable for the index of refraction of at least one material in the light-scattering color-conversion layer 23 to be approximately equal to or greater than the refractive index range of the EL element components and to be located within 500 nm (preferably 200 nm and more preferably 100 nm) of the side of the light-scattering color-conversion layer adjacent to the EL element. This is to insure that all of the light trapped in the organic layers 14 and transparent electrode 16 can experience the direction altering effects of the light-scattering color-conversion layer 23. If the light-scattering color-conversion layer 23 has a thickness less than one-tenth part of the wavelength of the emitted light, then the scattering particles 70 need not have such a preference for their refractive indices. In one embodiment, the light-scattering particles 70 have a different optical refractive index than the color-conversion material particles 72.

Whenever light crosses an interface between two layers of differing index (except for the case of total internal reflection), a portion of the light is reflected and another portion is refracted. Unwanted reflections can be reduced by the application of standard thin anti-reflection layers. Use of anti-reflection layers may be particularly useful on both sides of the encapsulating cover 20, for top emitters, and on both sides of the transparent substrate 10, for bottom emitters.

The scattering particles 70 can employ a variety of materials. For example, randomly located particles of titanium dioxide may be employed in a matrix of polymeric material. Alternatively, a more structured arrangement employing ITO, silicon oxides, or silicon nitrides may be used. Materials of the light scattering particles 70 can include organic materials (for example polymers or electrically conductive polymers) or inorganic materials. The organic materials may include, e.g., one or more of polythiophene, PEDOT, PET, or PEN. The inorganic materials may include, e.g., one or more of SiOₓ (x>1), SiNₓ (x>1), Si₃N₄, TiO₂, MgO, ZnO, Al₂O₃, SnO₂, In₂O₃, MgF₂, and CaF₂. The scattering particles 70 may comprise, for example, silicon oxides and silicon nitrides having a refractive index of 1.6 to 1.8 and doped with titanium dioxide having a refractive index of 2.5 to 3. Polymeric materials having refractive indices in the range of 1.4 to 1.6 may be employed having a dispersion of refractive elements of material with a higher refractive index, for example titanium dioxide. Shapes of refractive elements may be cylindrical, rectangular, or spherical, but it is understood that the shape is not limited thereto. The difference in refractive indices between scattering materials may be, for example, from 0.3 to 3, and a large difference is generally desired. The thickness of the scattering layer, or size of features in, or on the surface of, a scattering layer may be, for example, 0.03 to 50 μm. It is generally preferred to avoid diffractive effects in the scattering layer. Such effects may be avoided, for example, by locating features randomly or by ensuring that the sizes or distribution of the refractive elements are not the same as the wavelength of the color of light emitted by the device from the light-emitting area.

The light-scattering color-conversion layer 23 should be selected to get the light out of the OLED as quickly as possible so as to reduce the opportunities for re-absorption by the various layers of the OLED device. The total diffuse transmittance of the light-scattering color-conversion layer 23 coated on a glass support should be high (preferably greater than 80%).

Color-conversion materials that may be employed in the present invention are themselves also well-known. Such materials are typically fluorescent and/or phosphorescent materials that absorb light at higher frequencies (shorter wavelengths, e.g. blue) and emit light at different and lower frequencies (longer wavelengths, e.g. green or red). Such materials that may be employed for use in OLED devices in accordance with the present invention are disclosed, e.g., in U.S. Pat. Nos. 5,126,214, 5,294,870, and 6,137,459, patent publications US2005/0057176, and US2005/0057177, and specifically may include useful fluorescent emissive materials such as polycyclic aromatic compounds as described in I. B. Berlman, “Handbook of Fluorescence Spectra of Aromatic Molecules,” Academic Press, New York, 1971 and EP 1 009 041, the disclosures of which are incorporated by reference herein.

Color-conversion materials comprising tertiary aromatic amines with more than two amine groups that can be used include oligomeric materials. Another class of useful emissive materials (for host or dopants) include aromatic tertiary amines, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or an oligomeric arylamine. Exemplary monomeric triarylamines are illustrated by Klupfel, et al. U.S. Pat. No. 3,180,730. Other suitable triarylamines substituted with one or more vinyl radicals and/or comprising at least one active hydrogen containing group are disclosed by Brantley, et al. U.S. Pat. Nos. 3,567,450 and 3,658,520. A more preferred class of aromatic tertiary amines are those which include at least two aromatic tertiary amine moieties as described in U.S. Pat. Nos. 4,720,432 and 5,061,569.

The emissive material can also be a polymeric material, a blend of two or more polymeric materials, or a doped polymer or polymer blend. The emissive material can also include more than one nonpolymeric and polymeric materials with or without dopants. Nonpolymeric dopants can be molecularly dispersed into the polymeric host, or the dopant could be added by copolymerizing a minor constituent into the host polymer. Typical polymeric materials include, but are not limited to, substituted and unsubstituted poly(p-phenylenevinylene) (PPV) derivatives, substituted and unsubstituted poly(p-phenylene) (PPP) derivatives, substituted and unsubstituted polyfluorene (PF) derivatives, substituted and unsubstituted poly(p-pyridine), substituted and unsubstituted poly(p-pyridalvinylene) derivatives, and substituted, unsubstituted poly(p-phenylene) ladder and step-ladder polymers, and copolymers thereof as taught by Diaz-Garcia, et al. in U.S. Pat. No. 5,881,083 and references therein. The substituents include but are not limited to alkyls, cycloalkyls, alkenyls, aryls, heteroaryls, alkoxy, aryloxys, amino, nitro, thio, halo, hydroxy, and cyano. Typical polymers are poly(p-phenylene vinylene), dialkyl-, diaryl-, diamino-, or dialkoxy-substituted PPV, mono alkyl-mono alkoxy-substituted PPV, mono aryl-substituted PPV, 9,9′-dialkyl or diaryl-substituted PF, 9,9′-mono alky-mono aryl substituted PF, 9-mono alky or aryl substituted PF, PPP, dialkyl-, diamino-, diaryl-, or dialkoxy-substituted PPP, mono alkyl-, aryl-, alkoxy-, or amino-substituted PPP. In addition, polymeric materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS. The organic materials mentioned above are suitably deposited from a solvent with an optional binder to improve film formation.

Besides using organic fluorescent dyes as the down converters, recent results point to the viability of using inorganic quantum dots as the fluorescent compounds in the color converter layer. For example, colloidal CdSe/CdS heterostructure quantum dots have demonstrated quantum yields above 80%, A. P. Alivisatos, MRS Bulletin 18 (1998). The solid matrix containing the organic or inorganic fluorescent material should be transparent to visible wavelength light and capable of being deposited by inexpensive processes. Preferred solid matrices are transparent plastics, such as poly-vinyl acetate or PMMA. In doping the matrices with the organic dyes, the dye concentration needs to be kept just below where concentration quenching begins to occur. As such, the doping concentration would be in the 0.5-2% range for DCJTB and Coumarin 545T.

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890 issued May 8, 2001 to Boroson et al. In addition, barrier layers such as SiOₓ (x>1), Teflon, and alternating inorganic/polymeric layers are known in the art for encapsulation.

In particular, very thin layers of transparent encapsulating materials 24 may be deposited on the transparent electrode 16 to protect the EL element from environmental contamination such as water vapor or mechanical stress. In this case, the light-scattering color-conversion layer 23 may be deposited over the layers of encapsulating materials. This structure has the advantage of protecting the electrode 16 during the deposition of the light-scattering color-conversion layer 23. Preferably, the layers of transparent encapsulating material have a refractive index comparable to the first refractive index range of the transparent electrode 16 and/or organic layers 14, or is very thin (e.g., less than about 0.2 micron) so that wave guided light in the transparent electrode 16 and organic layers 14 will pass through the layers of transparent encapsulating material and be scattered by the light-scattering color-conversion layer 23. In one useful embodiment, the protective layer 24 may include combinations of metal oxides, silicon oxides, and silicon nitrides to provide transparency, encapsulation, protection, and a suitable refractive index.

OLED devices of this invention can employ various well-known optical effects in order to enhance their properties if desired. This includes optimizing layer thicknesses to yield maximum light transmission, providing dielectric mirror structures, replacing reflective electrodes with light-absorbing electrodes, providing anti-glare or anti-reflection coatings over the display, providing a polarizing medium over the display, or providing neutral density filters over the display. Filters, polarizers, and anti-glare or anti-reflection coatings may be specifically provided over the cover or as part of the cover.

The present invention may also be practiced with either active- or passive-matrix OLED devices. It may also be employed in display devices. In a preferred embodiment, the present invention is employed in a flat-panel OLED device composed of small molecule or polymeric OLEDs as disclosed in but not limited to U.S. Pat. No. 4,769,292, issued Sep. 6, 1988 to Tang et al., and U.S. Pat. No. 5,061,569, issued Oct. 29, 1991 to VanSlyke et al. Many combinations and variations of organic light-emitting displays can be used to fabricate such a device, including both active- and passive-matrix OLED displays having either a top- or bottom-emitter architecture.

The invention has been described in detail with particular reference to certain preferred embodiments thereof, but it will be understood that variations and modifications can be effected within the spirit and scope of the invention.

### Parts List

10 substrate
12 electrode
14 organic layer(s)
16 transparent electrode
18 low-index element
20 cover
23, 23R, 23G, 23B light-scattering color-conversion material layer
24 protective layer
30 thin-film transistors
32 planarization layer
34 planarization layer
40, 40A, 40B, 40C color filters
50, 50R, 50G, 50B light-emitting areas
60 adhesive
70 light-scattering particle
72 color-conversion material
74 transparent matrix
76 first side
78 opposite side
100 form EL on substrate step
102 form scattering layer on OLED step
104 form black matrix on cover step
106 form color filter on cover step
108 form color-conversion layer step
110 align cover to substrate step
112 affix cover to substrate step

1. A light-scattering color-conversion material layer having two sides, comprising first light-scattering particles intermixed with second different color-conversion material particles, wherein the concentration of the light scattering particles is greater towards a first side of the layer relative to the concentration of light-scattering particles towards the opposite side of the layer, or wherein the concentration of the color-conversion material particles is less towards the first side of the layer relative to the concentration of color-conversion material particles towards the opposite side of the layer.

2. A light-scattering color-conversion material layer of claim 1, wherein the concentration of the light scattering particles is greater towards a first side of the layer relative to the concentration of light-scattering particles towards the opposite side of the layer, and the concentration of the color-conversion material particles is less towards the first side of the layer relative to the concentration of color-conversion material particles towards the opposite side of the layer.

3. A light-scattering color-conversion material layer of claim 1, wherein first light-scattering particles are located within 500 nm of the first side of the layer over more than half of the area of the first side.

4. A light-scattering color-conversion material layer of claim 1, wherein the light-scattering particles have a first average size and the color-conversion particles have a second average size smaller than the first average size.

5. The light-scattering color-conversion material layer of claim 1, wherein the light-scattering particles have an average maximum dimension size greater than 400 nm.

6. The light-scattering color-conversion material layer of claim 1, wherein the light-scattering particles have an average maximum dimension size less than two microns.

7. The light-scattering color-conversion material layer of claim 1, wherein the color-conversion material particles have an average maximum dimension size less than 400 nm.

8. The light-scattering color-conversion material layer of claim 1 further comprising an adhesive binder and/or surfactant.

9. The light-scattering color-conversion material layer of claim 1 further comprising a matrix in which either or both of the light-scattering particles and/or color-change material particles are dispersed.

10. The light-scattering color-conversion material layer of claim 9 wherein the matrix is a polymer, resin, or urethane, or a curable material.

11. The light-scattering color-conversion material layer of claim 1 wherein the layer is self-supporting.

12. The light-scattering color-conversion material layer of claim 1 wherein the layer is coated on a support.

13. A method of forming a light-scattering color-conversion material layer comprising the steps of:
coating a first layer comprising light-scattering particles on a substrate; and
coating a second layer comprising color-conversion material particles over the first layer, wherein the color-conversion material particles and light-scattering particles intermix at the interface of the first and second layers to form an integral layer, wherein the concentration of the light scattering particles is greater towards a first side of the integral layer relative to the concentration of light-scattering particle towards the opposite side of the integral layer, or wherein the concentration of the color-conversion material particles is less towards the first side of the integral layer relative to the concentration of color-conversion material particle towards the opposite side of the integral layer.

14. The method of claim 13, further comprising the step of mixing the light-scattering particles and/or color-change material particles in a matrix material and the mixture is coated on the substrate.

15. The method of claim 13, further comprising the steps of mixing the light-scattering particles in a solvent and mixing the color-change material particles in a matrix material, and wherein the solvent mixture is coated as the first layer, and the matrix mixture is coated as the second layer.

16. The method of claim 13, further comprising the steps of mixing the light-scattering particles in a first solvent and mixing the color-change material particles in a second solvent, and wherein the first solvent mixture is coated as the first layer, and the second solvent mixture is coated as the second layer.

17. A light emitting device, comprising:
one or more EL elements formed on a substrate; and
a light-scattering color-conversion material layer optically coupled with the EL element,
wherein light emitted from the EL element at a first frequency is absorbed and re-emitted by the color-conversion material at a second, lower frequency and light emitted from, and entrapped in, the EL element is extracted by the light-scattering particles, wherein the concentration of the light scattering particles is greater towards a first side of the layer adjacent to the EL element relative to the concentration of light-scattering particle towards the opposite side of the layer, and wherein the concentration of the color-conversion material particles is less towards the first side of the layer relative to the concentration of color-conversion material particle towards the opposite side of the layer.

18. The light emitting device of claim 17, wherein the EL element comprises an OLED element.

19. The light emitting device of claim 17, further comprising a cover through which light is emitted, and a low-index layer formed between the cover and the light-scattering color-conversion material layer.

20. The light emitting device of claim 17, wherein light is emitted through the substrate and further comprising a low-index layer formed between the substrate and the light-scattering color-conversion material layer.
